(19) United States
(12) Patent Application Publication
(10) Pub. No.: US 2020/0265210 A1
(43) Pub. Date: Aug. 20, 2020

(54) SEMICONDUCTOR DEVICE AND DISPLAY PANEL

(71) Applicant: INCOFLEX SEMICONDUCTOR TECHNOLOGY CO., LTD., Shaanxi (CN)

(72) Inventors: BO-JHANG SUN, SHAANXI (CN); PINGI SHIH, SHAANXI (CN)

(21) Appl. No.: 16/777,524

(22) Filed: Jan. 30, 2020

(30) Foreign Application Priority Data
Jan. 31, 2019 (CN) 201910100991.3

(51) Int. Cl. G06K 9/00; H01L 27/32

(52) U.S. Cl. CPC G06K 9/00013; G02F 1/1362; H01L 27/3234; H01L 27/3211

(57) ABSTRACT

A semiconductor device includes a plurality of pixel groups disposed on a surface of a substrate for displaying an image. Each pixel group includes a colored pixel and a plurality of functional subpixels separated from each other, wherein the colored pixel includes a plurality of colored subpixels. A number x of functional subpixels are arranged adjacent to the colored subpixel in a pixel group in a row direction, wherein x is between 0 and 4, a number y of functional subpixels are arranged adjacent to the colored subpixel in the pixel group in a column direction, wherein y is between 0 and 4, a number z of functional subpixels are arranged adjacent to the colored subpixel in the pixel group in a diagonal direction, wherein z is between 0 and 4, and x, y and z are not all equal to 0.

### TECHNICAL FIELD

The present disclosure relates to a semiconductor device and a display panel, and more particularly, to a display panel with high light transmittance, high storage capacitance and/or full-screen fingerprint function.

### BACKGROUND ART

With the diversity of consumer application needs, the improvement of display resolution and the progress of technology, the design of advanced display applications shows more flexibilities and realize many unseen terminal applications such as in-display fingerprint reader. Fingerprints are unique to every individual person. With the development of technology, a variety of display devices with fingerprint recognition functions such as mobile phones, tablet computers, and smart wearable devices are appearing on the market. With the in-display fingerprint reader, a user only needs to touch the fingerprint recognition sensor of the display device with his or her finger to perform authentication so as to activate the display device. However, a major drawback with fingerprint recognition sensors is that the sensors also receive crosstalk signals from other locations, thus decreasing the authentication accuracy.

Due to the structural limitation of the fingerprint module, the fingerprint recognition sensor is confined to a fixed area of the mobile phone. An upper surface of the display device may be divided into a transparent area and a peripheral area. The fingerprint module is incorporated in the peripheral area. Thus, the fingerprint recognition function can only be achieved in the peripheral area of the display device and the fingerprint recognition function cannot be realized in the transparent area of the display device. The fingerprint module in the peripheral area also makes the frame of the display device larger, which results in a low screen-to-body ratio.

### SUMMARY

The present disclosure provides a semiconductor device including a substrate. The substrate includes a pixel layer disposed on a surface of the substrate for displaying an image. The pixel layer includes a plurality of pixel groups, and each pixel group includes a colored pixel and a plurality of functional subpixels separated from each other, wherein the colored pixel includes a plurality of colored subpixels. A number x of functional subpixels are arranged adjacent to the colored subpixel in a pixel group in a row direction, wherein x is between 0 and 4, a number y of functional subpixels are arranged adjacent to the colored subpixel in the pixel group in a column direction, wherein y is between 0 and 4, a number z of functional subpixels are arranged adjacent to the colored subpixel in the pixel group in a diagonal direction, wherein z is between 0 and 4, and x, y and z are not all equal to 0.

The present disclosure provides a display panel including a substrate. The substrate includes a plurality of colored subpixels and a plurality of functional subpixels. A portion of the plurality of functional subpixels surrounds at least one of the plurality of colored subpixels, and at least one of the plurality of functional subpixels is disposed between two adjacent colored subpixels of the plurality of colored subpixels.

### BRIEF DESCRIPTION OF THE DRAWINGS

The accompanying drawings described below further illustrate the present disclosure without placing any limitations on the present disclosure.

FIG. 1 is a schematic view of a display panel according to an embodiment of the present disclosure.

FIG. 2 is a schematic view of a display panel according to an embodiment of the present disclosure.

FIG. 3 is a schematic view of a display panel according to an embodiment of the present disclosure.

FIG. 4 is a schematic view of a display panel according to an embodiment of the present disclosure.

FIG. 5 is a schematic view of a display panel according to an embodiment of the present disclosure.

### EMBODIMENTS

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±50, less than or equal to ±4°, less than or equal to ±30, less than or equal to ±2°, less than or equal to ±10, less than or equal to ±0.5°, less than or equal to ±0.1°, or less than or equal to ±0.05°. For example, “substantially” perpendicular can refer to a range of angular variation relative to 90° that is less than or equal to ±100, such as less than or equal to ±50, less than or equal to ±4°, less than or equal to ±30, less than or equal to ±20, less than or equal to ±1°, less than or equal to ±0.5°, less than or equal to ±0.10, or less than or equal to ±0.050.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

As used herein, the terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a tool, a system, a device, or an apparatus that “comprises,” “has,” “includes” or “contains” one or more elements possesses those one or more elements, but is not limited to possessing only those one or more elements. Likewise, an element of a tool, a system, a device, or an apparatus that “comprises,” “has,” “includes” or “contains” one or more features possesses those one or more features, but is not limited to possessing only those one or more features.

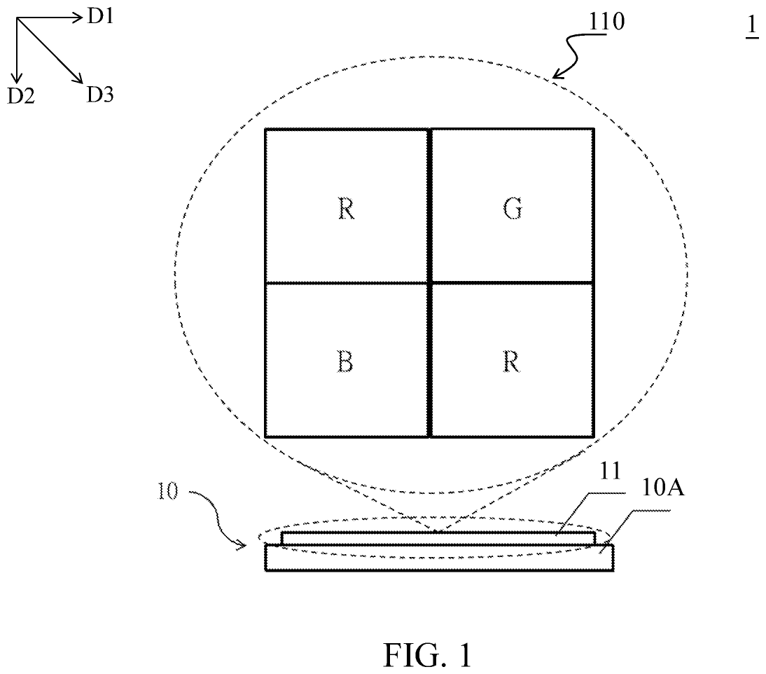

Referring to FIG. 1, FIG. 1 is a schematic view of a display panel according to an embodiment of the present disclosure. The display panel 1 includes a semiconductor device 10. In some embodiments, the semiconductor device 10 includes a substrate 10A. In some embodiments, the substrate 10A may be a transparent substrate, which may be made of glass, polyethylene terephthalate (PET), polycarbonate (PC), or polymethylmethacrylate (PMMA).

The substrate 10A includes a pixel layer 11 disposed on a surface of the substrate 10A for displaying an image. The pixel layer 11 includes a plurality of pixel groups 110, and each pixel group 110 includes a colored pixel.

The colored pixel includes a plurality of colored subpixels. The colored subpixels may include a red subpixel R, a green subpixel G and a blue subpixel B. The colored subpixels may further include another red subpixel R, another green subpixel G, or another blue subpixel B. The red subpixel R, the green subpixel G and the blue subpixel B may be configured to display different colors. For example, the red subpixel R may be configured to display the color red, the green subpixel G may be configured to display the color green and the blue subpixel B may be configured to display the color blue.

Although the colored subpixels illustrated in FIG. 1 are square in shape, the colored subpixels may have other suitable shapes. In addition, the number of colored subpixels in one pixel group 110 may be, but is not limited to, 4. Alternatively, the number of colored subpixels may be altered and there may be other suitable colored subpixels configured to display different colors, such as yellow, white or other colors.

Take the red subpixel R in the upper left corner as an origin of coordinates. The green subpixel G in the upper right corner as shown in FIG. 1 is adjacent to the origin red subpixel R in a row direction D1. The blue subpixel B in the bottom left corner is adjacent to the origin red subpixel R in a column direction D2. The other red subpixel R in the bottom right corner is adjacent to the origin red subpixel R in a diagonal direction D3.

Referring to FIG. 1 again, the arrangement of the colored subpixels in the pixel group 110 includes, from left to right, top to bottom, the red subpixel R, the green subpixel G, then the blue subpixel B and the red subpixel R, but is not limited thereto. The configuration of the colored subpixels may be altered according to the design or other considerations. For example, the arrangement of the colored subpixels in a pixel group 110 may include, from left to right, top to bottom, the blue subpixel B, the green subpixel G, then the red subpixel R and the blue subpixel B.

The display panel of the present disclosure is not limited to the above-mentioned embodiments, and may include other different embodiments. To simplify the description and for the convenience of comparison between each of the embodiments of the present disclosure, the identical components in each of the following embodiments are marked with identical numerals. For making it easier to compare the differences between the embodiments, the following description will detail the dissimilarities among different embodiments and the identical features will not be redundantly described.

To further improve the transparency and to realize various terminal applications such as an in-display fingerprint reader, other embodiments of the present disclosure further provide semiconductor devices and display panels with particular pixel layouts. The pixel layout designs increase the transparency of the display panels and may release more space for accommodating other functional elements such as the fingerprint sensors.

In accordance with some embodiments of the present disclosure, the display panel downsizes the colored subpixel into a smaller subpixel in each pixel group. Thus, extra space in each pixel group is obtained and can be designed to have different functions. For instance, the extra space in each pixel group may be designed to incorporate the fingerprint modules. In some embodiments, a storage circuit may be disposed in the extra space of each pixel group. In other embodiments, a light-transmitting region may be designed in the extra space of the pixel group. Accordingly, the display panel of the present disclosure may have greater light transmittance, greater fingerprint scanning area and more storage for the circuit.

In the following embodiments of the present disclosure, a display panel with a resolution of wide quad high definition (WQHD) resolution is used for description, but the present disclosure is not limited thereto. WQHD is a display resolution of 2560×1440 pixels in a 16:9 aspect ratio.

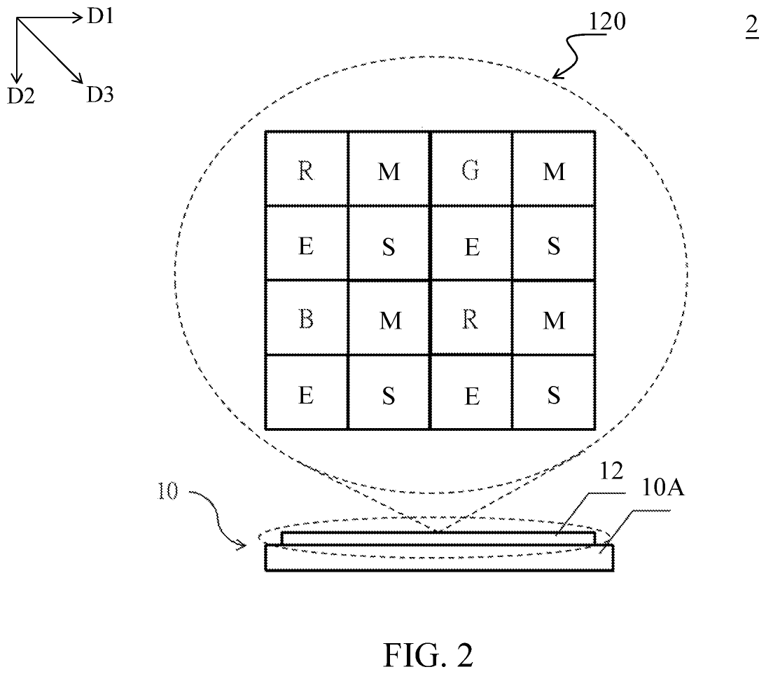

FIG. 2 is a schematic view of a display panel according to an embodiment of the present disclosure. The pixel layer 12 of the display panel 2 includes a plurality of pixel groups 120. Each pixel group 120 includes a colored pixel and a plurality of functional subpixels separated from each other. The colored pixel includes a plurality of colored subpixels. In some embodiments, a portion of the functional subpixels surround a colored subpixel. At least one of the functional subpixels may be disposed between two adjacent colored subpixels. In some embodiments, an area of each colored subpixel is substantially the same as an area of each functional subpixel.

The colored subpixel may include a red subpixel R, a green subpixel G and a blue subpixel B as described above. The functional subpixels may include light-transmitting subpixels E, fingerprint-sensing subpixels S and storage circuit subpixels M adjacent to the colored subpixel in the pixel group 120. In some embodiments, the light-transmitting subpixels E may be transparent to increase the total transmittance of the display panel 1. In other embodiments, the light-transmitting subpixels E may be configured for see-through viewing of an environment.

The fingerprint-sensing subpixels S may be configured to perform fingerprint recognition and/or verification. In some embodiments, the fingerprint-sensing subpixels S may include a photosensitive device integrated into the substrate 10A through an embedded technology or an in-cell technology. The photosensitive device may capture an optical image of the user's finger and detect unique patterns on the surface of user's fingerprint, such as ridges or unique marks, by analyzing the lightest and darkest areas of the image. In some embodiments, the photosensitive device may be metal mesh sensors, indium tin oxide sensors, or silver nanowire sensors.

In some embodiments, a touch panel (not shown) with touch sensors may be disposed over the photosensitive device on the substrate 10A. The touch panel is attached to the substrate 10A such that both the touch function and the fingerprint recognition function may be implemented in the display panel 2 of a terminal device. The touch sensors may be metal mesh sensors, indium tin oxide sensors, or silver nanowire sensors.

In some embodiments, the photosensitive device includes at least a sensing electrode layer (not shown) and an emitting electrode layer (not shown). The sensing electrode layer and the emitting electrode layer may be respectively disposed on the front and back surfaces of the substrate 10A of the display panel 2 such that the photosensitive device located above the display panel may identify the user's fingerprint without affecting the touch function of the touch sensors under the display panel 2.

Arranging the sensing electrode layer and the emitting electrode layer of the photosensitive device to be respectively disposed on the front and back sides of the substrate 10A may reduce the number of the photosensitive devices on a single surface of the substrate 10A. Thus, a total thickness of the display panel 2 may be reduced. Further, the influence of the photosensitive device on the display panel 2 below it may be reduced, and the light transmittance and resolution of the display panel 2 may be preserved.

In some embodiments, the sensing electrode and the emitting electrode are arranged alternatively. A grid composed of the sensing electrode and the emitting electrode may be a rhombic grid, a rectangular grid, or a parallelogram grid. To ensure that the grid formed by the sensing electrodes and the emitting electrodes of the photosensitive device will not block the display panel 2, the size of the grid is designed to correspond to the resolution of the display panel 2. Thus, moiré patterns are less likely to appear on the display panel 2, and the display effect of the display panel 2 may be improved.

In some embodiments, the storage circuit subpixels M include a memory device. The storage circuit subpixels M can be configured to store the digitized signals from each subpixel. The storage circuit subpixels M may be configured to store the user's fingerprint data. The fingerprint-sensing subpixels S may be configured to work with the storage circuit subpixels M to perform fingerprint recognition and/or verification. In some embodiments, the storage circuit subpixel M may have a 2T1C layout.

Take the colored subpixel (R, G or B) in the upper left corner as the origin of coordinates. As shown in FIG. 2, a number x of functional subpixels are arranged adjacent to the colored subpixel (R, G or B) in a pixel group 120 in a row direction D1, wherein x is between 0 and 4. In some embodiments, x is between 0 and 3. In other embodiments, x is between 0 and 2. A number y of functional subpixels are arranged adjacent to the colored subpixel (R, G or B) in the pixel group 120 in a column direction D2, wherein y is between 0 and 4. In some embodiments, y is between 0 and 3. In other embodiments, y is between 0 and 2. A number z of functional subpixels are arranged adjacent to the colored subpixel (R, G or B) in the pixel group 120 in a diagonal direction D3, wherein z is between 0 and 4. In some embodiments, z is between 0 and 3. In other embodiments, z is between 0 and 2. The values x, y and z are not all equal to 0.

In some embodiments, a number m of light-transmitting subpixels E, a number n of fingerprint-sensing subpixels S, and a number k of storage circuit subpixels M are adjacent to the colored subpixel (R, G or B) in the pixel group 120 in the row direction D1, wherein m+n+k=x. A number p of light-transmitting subpixels E, a number q of fingerprint-sensing subpixels S, and a number r of storage circuit subpixels M are adjacent to the colored subpixel (R, G or B) in the pixel group 120 in the column direction D2, wherein p+q+r=y. A number d of light-transmitting subpixels, a number e of fingerprint-sensing subpixels and a number f of storage circuit subpixels are adjacent to the colored subpixel (R, G or B) in the pixel group 120 in the diagonal direction D3, wherein d+e+f=z.

Referring to FIG. 2 again, one functional subpixel is arranged adjacent to the colored subpixel (R, G or B) in the pixel group 120 in the row direction D1; thus, x=1. For instance, a storage circuit subpixel M is adjacent to the colored subpixel (R, G or B) in the row direction D1; thus, x=k=1. Another functional subpixel is arranged adjacent to the colored subpixel (R, G or B) in the pixel group 120 in the column direction D2; thus y=1. In such case, a light-transmitting subpixel E is adjacent to the colored subpixel (R, G or B) in the column direction D2; thus, y=p=1. One functional subpixel is arranged adjacent to the colored subpixel (R, G or B) in the pixel group 120 in the diagonal direction D3; thus, z=1. As shown in FIG. 2, a fingerprint-sensing subpixel S is adjacent to the colored subpixel (R, G or B) in the diagonal direction D3; thus, z==e=1. In some embodiments, p is between 1 and 4, q is between 0 and 3 and r is between 0 and 3. In other embodiments, m is between 0 and 3, n is between 0 and 3, k is between 1 and 4, d is between 0 and 3, e is between 1 and 4, and f is between 0 and 3.

Take the colored subpixel (R, G or B) in the upper left corner as the origin of coordinates again. The arrangement of the colored subpixel and functional subpixels in the upper left corner of the pixel group 120 includes, from left to right, top to bottom, the colored subpixel (R, G or B), the storage circuit subpixel M, then the light-transmitting subpixel E and the fingerprint-sensing subpixel S, but is not limited thereto. The configuration of the functional subpixels may be altered according to the design or other considerations. Further, although the functional subpixels illustrated in FIG. 2 are square in shape, the functional subpixels may have other suitable shapes. In addition, the number of functional subpixels in one pixel group 120 may be, but is not limited to, 12. Alternatively, the number of functional subpixels may be altered and there may be other suitable functional subpixels configured to have different functions.

In the area of the colored subpixels and the functional subpixels arranged in a 2 by 2 grid in the pixel group 120, each of the colored subpixels (R, G or B) is surrounded by at least a storage circuit subpixel M, at least a light-transmitting subpixel E and at least a fingerprint-sensing subpixel S. In other words, at least one storage circuit subpixel M, at least one light-transmitting subpixel E and at least one fingerprint-sensing subpixel S are arranged in the upper subpixel area, the lower subpixel area, the left subpixel area or the right subpixel area relative to the location of the colored subpixel (R, G or B).

In the present embodiment, the areas of the colored subpixel (R, G or B), the storage circuit subpixel M, the light-transmitting subpixel E and the fingerprint-sensing subpixel S are substantially the same. According to different product requirements, each colored subpixel and each functional subpixel respectively occupies one-fourth of the area of the pixel group 120. Therefore, the display panel 2 may have greater light transmittance, greater fingerprint scanning area and extra storage circuit at the same time.

In the present embodiment, a full-screen fingerprint touch display panel is provided. In some embodiments, the display panel 2 includes an active matrix liquid crystal display (AMLCD) panel or an active matrix organic light-emitting diode (AMOLED) display panel, but is not limited thereto. Take the AMLCD panel as an example. The AMLCD panel may include a protecting cover, a touch panel, a color filter, a liquid crystal layer, a pixel layer and a glass substrate.

The touch sensor is disposed in the touch panel to achieve the integration of the touch sensor into the semiconductor device 10. In some embodiments, the touch sensor is integrated in the AMLCD panel or the AMOLED display panel through an in-cell technology to ensure the touch function is provided in the display panel 2.

A glass cover layer may be subsequently attached to the liquid crystal panel with the semiconductor device 10. In some embodiments, the glass cover layer may be any kind of silicate glass. The material of the silicate glass includes SiO2, which has acid resistance, alkali resistance and abrasion resistance. Thus, the glass cover layer may protect the internal structure of the display panel 2.

According to the embodiment of the present disclosure, the semiconductor device 10 of the display panel 2 may be applied to various terminal devices having a display function. The terminal devices may have the advantages of the semiconductor device 10 of the display panel 2, which will not be redundantly described. Specifically, the terminal device may be a smart watch, a mobile phone or a tablet computer. The semiconductor device 10 provided by the present disclosure is used to optimize the terminal device to realize the fingerprint-related technology in the terminal device. For instance, the fingerprint-related technology may include functions of fingerprint biometric payment and fingerprint encryption incorporated in the smart watch. As for the mobile phone and the tablet computer, the semiconductor device 10 may increase the screen-to-body ratio of such devices and achieve full-screen fingerprint recognition, which improves the aesthetics and operability of the mobile phone or tablet computer. In addition, the terminal device provided by the present invention may be a display device, such as a navigation device of a business center, a display of a desktop computer, or a display of a notebook computer.

The display panel of the present disclosure is not limited to the above-mentioned embodiments, and may include other different embodiments. To simplify the description and for the convenience of comparison between each of the embodiments of the present disclosure, the identical components in each of the following embodiments are marked with identical numerals. For making it easier to compare the difference between the embodiments, the following description will detail the dissimilarities among different embodiments and the identical features will not be redundantly described.

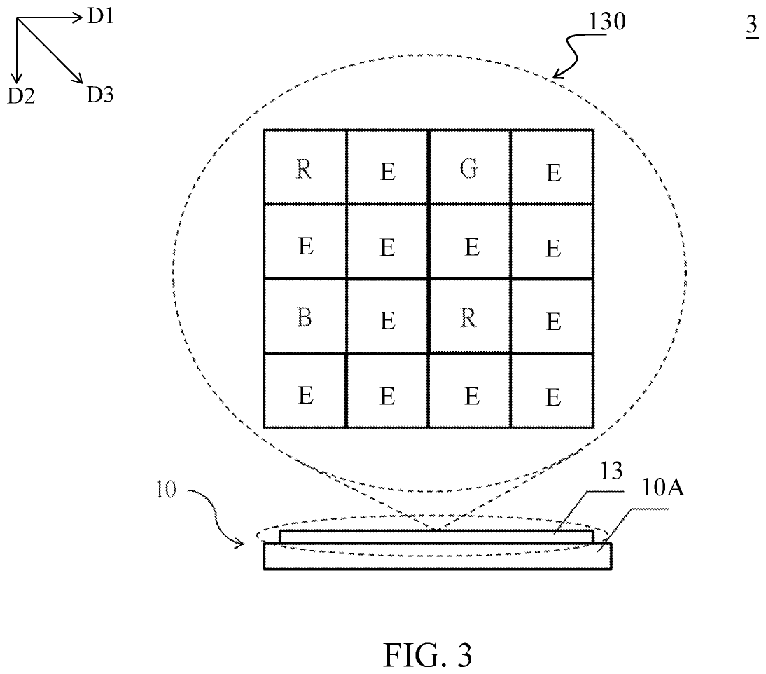

FIG. 3 is a schematic view of a display panel according to an embodiment of the present disclosure. The pixel layer 13 of the display panel 3 includes a plurality of pixel groups 130. Each pixel group 130 includes a plurality of colored subpixels and a plurality of functional subpixels separated from each other. The colored subpixels may include a red subpixel R, a green subpixel G and a blue subpixel B as described above. In some embodiments, the functional subpixels may mainly include the light-transmitting subpixels E.

As shown in FIG. 3, one functional subpixel is arranged adjacent to the colored subpixel (R, G or B) in the pixel group 130 in the row direction D1; thus, x=1. For instance, a light-transmitting subpixel E is adjacent to the colored subpixel (R, G or B) in the row direction D1, thus, x=m=1. Another functional subpixel is arranged adjacent to the colored subpixel (R, G or B) in the pixel group 130 in the column direction D2; thus, y=1. In such case, a light-transmitting subpixel E is adjacent to the colored subpixel (R, G or B) in the column direction D2; thus, y=p=1. One functional subpixel is arranged adjacent to the colored subpixel (R, G or B) in the pixel group 130 in the diagonal direction D3; thus, z=1. As shown in FIG. 3, a light-transmitting subpixel E is adjacent to the colored subpixel (R, G or B) in the diagonal direction D3; thus, z=d=1. In some embodiments, m is between 1 and 4, n is between 0 and 3, and k is between 0 and 3. In other embodiments, p is between 1 and 4, q is between 0 and 3, r is between 0 and 3, d is between 1 and 4, e is between 0 and 3, and f is between 0 and 3.

In the present embodiment, each of the colored subpixels (R, G or B) is surrounded by the light-transmitting subpixels E. In other words, the light-transmitting subpixels E are arranged in the upper subpixel area, the lower subpixel area, the left subpixel area and the right subpixel area relative to the location of the colored subpixel (R, G or B). Three-fourths of the total area of the pixel group 130 may be occupied by the light-transmitting subpixels E. Therefore, the display panel 3 may have greater light-transmittance compared to the aforementioned embodiments.

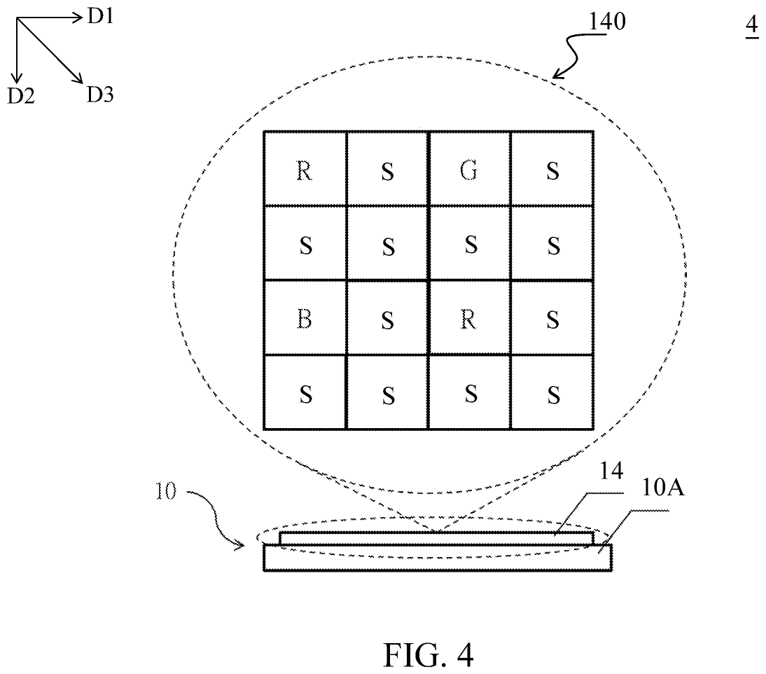

FIG. 4 is a schematic view of a display panel according to an embodiment of the present disclosure. The pixel layer 14 of the display panel 4 includes a plurality of pixel groups 140. Each pixel group 140 includes a plurality of colored subpixels and a plurality of functional subpixels separated from each other. The colored subpixels may include a red subpixel R, a green subpixel G and a blue subpixel B as described above. In some embodiments, the functional subpixels may mainly include the fingerprint-sensing subpixels S.

As shown in FIG. 4, one functional subpixel is arranged adjacent to the colored subpixel (R, G or B) in the pixel group 140 in the row direction D1; thus, x=1. For instance, a fingerprint-sensing subpixel S is adjacent to the colored subpixel (R, G or B) in the row direction D1; thus, x=n=1. Another functional subpixel is arranged adjacent to the colored subpixel (R, G or B) in the pixel group 140 in the column direction D2; thus, y=1. In such case, a fingerprint-sensing subpixel S is adjacent to the colored subpixel (R, G or B) in the column direction D2; thus, y=q=1. One functional subpixel is arranged adjacent to the colored subpixel (R, G or B) in the pixel group 140 in the diagonal direction D3; thus, z=1. As shown in FIG. 4, a fingerprint-sensing subpixel S is adjacent to the colored subpixel (R, G or B) in the diagonal direction D3; thus, z=e=1. In some embodiments, m is between 0 and 3, n is between 1 and 4, and k is between 0 and 3. In other embodiments, p is between 0 and 3, q is between 1 and 4, r is between 0 and 3, d is between 0 and 3, e is between 1 and 4, and f is between 0 and 3.

In the present embodiment, each of the colored subpixels (R, G or B) is surrounded by the fingerprint-sensing subpixels S. In other words, the fingerprint-sensing subpixels S are arranged in the upper subpixel area, the lower subpixel area, the left subpixel area and the right subpixel area relative to the location of the colored subpixel (R, G or B). Three-fourths of the total area of the pixel group 140 may be occupied by the fingerprint-sensing subpixels S. Therefore, the display panel 4 may have greater fingerprint-scanning area compared to the aforementioned embodiments.

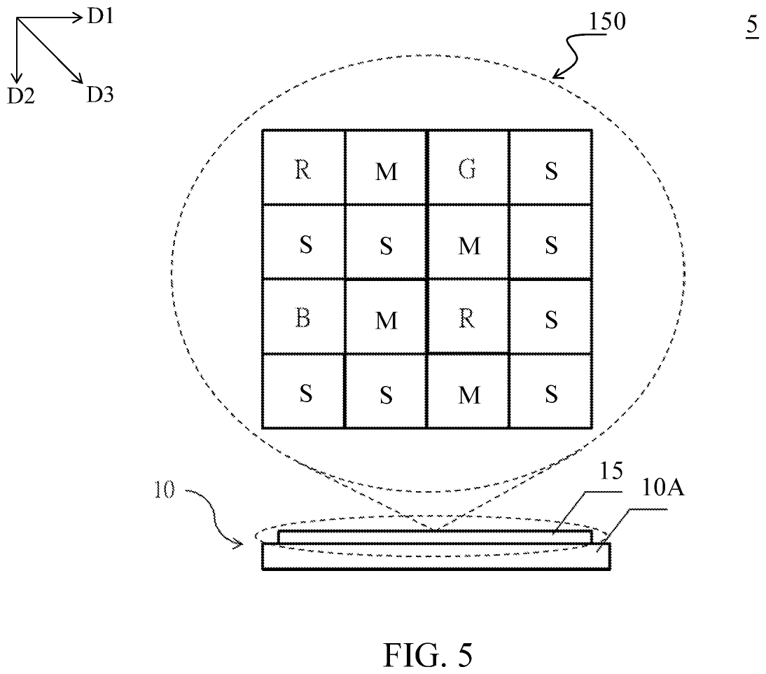

FIG. 5 is a schematic view of a display panel according to an embodiment of the present disclosure. The pixel layer 15 of the display panel 5 includes a plurality of pixel groups 150. Each pixel group 150 includes a plurality of colored subpixels and a plurality of functional subpixels separated from each other. The colored subpixels may include a red subpixel R, a green subpixel G and a blue subpixel B as described above. In some embodiments, the functional subpixels may mainly include the fingerprint-sensing subpixels S and the storage circuit subpixels M.

As shown in FIG. 5, one functional subpixel is arranged adjacent to the colored subpixel (R, G or B) in the pixel group 150 in the row direction D1; thus, x=1. Another functional subpixel is arranged adjacent to the colored subpixel (R, G or B) in the pixel group 150 in the column direction D2; thus, y=1. One functional subpixel is arranged adjacent to the colored subpixel (R, G or B) in the pixel group 140 in the diagonal direction D3; thus, z=1.

As shown in the left side of FIG. 5, a storage circuit subpixel M is adjacent to the colored subpixel (R, G or B) in the row direction D1; thus, x=k=1. A fingerprint-sensing subpixel S is adjacent to the colored subpixel (R, G or B) in the column direction D2; thus, y=q=1. A fingerprint-sensing subpixel S is adjacent to the colored subpixel (R, G or B) in the diagonal direction D3, thus, z=e=1. In some embodiments, m is between 0 and 3, n is between 0 and 3, and k is between 1 and 4. In other embodiments, p is between 0 and 3, q is between 1 and 4, r is between 0 and 3, d is between 0 and 3, e is between 1 and 4, and f is between 0 and 3.

As shown in the right side of FIG. 5, a fingerprint-sensing subpixel S is adjacent to the colored subpixel (R, G or B) in the row direction D1; thus, x=n=1. A storage circuit subpixel M is adjacent to the colored subpixel (R, G or B) in the column direction D2; thus, y=r=1. A fingerprint-sensing subpixel S is adjacent to the colored subpixel (R, G or B) in the diagonal direction D3; thus, z=e=1. In some embodiments, m is between 0 and 3, n is between 1 and 4, and k is between 0 and 3. In other embodiments, p is between 0 and 3, q is between 0 and 3, r is between 1 and 4, d is between 0 and 3, e is between 1 and 4 and f is between 0 and 3.

In the present embodiment, each of the colored subpixels (R, G or B) is surrounded by two fingerprint-sensing subpixels S and one storage circuit subpixel M. The area of the storage circuit subpixel M is substantially the same as the area of the colored subpixel (R, G or B). In the present embodiment, one-half of the total area of the pixel group 150 may be occupied by the fingerprint-sensing subpixels S. and one-fourth of the total area of the pixel group 150 may be occupied by the storage circuit subpixel M. Therefore, the display panel 4 may have greater fingerprint scanning area and extra storage circuit at the same time.

Given the aforementioned configurations and arrangements, the semiconductor device and the display panel of the present disclosure downsize the colored subpixel into a smaller subpixel in each pixel group. Thus, extra space is obtained and can be designed to have different functions. The extra space may be designed to incorporate the photosensitive devices, and thus a full-screen fingerprint touch display panel may be obtained. In some embodiments, one-half of the extra space is used for fingerprint sensing and part of the extra space may be used to install a storage circuit. Accordingly, the display panel of the present disclosure may have greater light transmittance, greater fingerprint scanning area and more storage for the circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a pixel layer disposed on a surface of the substrate for displaying an image, wherein the pixel layer comprises a plurality of pixel groups, and each pixel group comprises a colored pixel and a plurality of functional subpixels separated from each other, wherein the colored pixel comprises a plurality of colored subpixels;
wherein a number x of functional subpixels are arranged adjacent to the colored subpixel in a pixel group in a row direction, wherein x is between 0 and 4, a number y of functional subpixels are arranged adjacent to the colored subpixel in the pixel group in a column direction, wherein y is between 0 and 4, a number z of functional subpixels are arranged adjacent to the colored subpixel in the pixel group in a diagonal direction, wherein z is between 0 and 4, and x, y and z are not all equal to 0.

2. The semiconductor device of claim 1, wherein the functional subpixels further comprise:
a number m of light-transmitting subpixels, a number n of fingerprint-sensing subpixels and a number k of storage circuit subpixels adjacent to the colored subpixel in the pixel group in the row direction, wherein m+n+k=x:
a number p of light-transmitting subpixels, a number q of fingerprint-sensing subpixels and a number r of storage circuit subpixels adjacent to the colored subpixel in the pixel group in the column direction, wherein p+q+r=y; and
a number d of light-transmitting subpixels, a number e of fingerprint-sensing subpixels and a number f of storage circuit subpixels adjacent to the colored subpixel in the pixel group in the diagonal direction, wherein d+e+f=z.

3. The semiconductor device of claim 2, wherein p is between 1 and 4, q is between 0 and 3, and r is between 0 and 3.

4. The semiconductor device of claim 3, wherein m is between 1 and 4, n is between 0 and 3, k is between 0 and 3, d is between 1 and 4, e is between 0 and 3, and f is between 0 and 3.

5. The semiconductor device of claim 3, wherein m is between 0 and 3, n is between 0 and 3, k is between 1 and 4, d is between 0 and 3, e is between 1 and 4, and f is between 0 and 3.

6. The semiconductor device of claim 2, wherein d is between 0 and 3, e is between 1 and 4, and f is between 0 and 3.

7. The semiconductor device of claim 6, wherein m is between 0 and 3, n is between 1 and 4, k is between 0 and 3, p is between 0 and 3, q is between 1 and 4, and r is between 0 and 3.

8. The semiconductor device of claim 6, wherein m is between 0 and 3, n is between 0 and 3, k is between 1 and 4, p is between 0 and 3, q is between 1 and 4, and r is between 0 and 3.

9. The semiconductor device of claim 6, wherein m is between 0 and 3, n is between 1 and 4, k is between 0 and 3, p is between 0 and 3, q is between 0 and 3 and r is between 1 and 4.

10. The semiconductor device of claim 6, wherein m is between 0 and 3, n is between 0 and 3, k is between 1 and 4, p is between 1 and 4, q is between 0 and 3, and r is between 0 and 3.

11. The semiconductor device of claim 2, wherein the storage circuit subpixels comprise a memory device.

12. The semiconductor device of claim 2, wherein the fingerprint-sensing subpixels comprise a photosensitive device, and the photosensitive device is integrated in the substrate through an embedded technology.

13. The semiconductor device of claim 1, wherein an area of each colored subpixel is substantially the same as an area of each functional subpixel.

14. The semiconductor device of claim 1, wherein the colored subpixels comprise a red subpixel, a green subpixel and a blue subpixel.

15. A display panel, comprising:
a substrate comprising a plurality of colored subpixels and a plurality of functional subpixels;
wherein a portion of the plurality of functional subpixels surrounds at least one of the plurality of colored subpixels, and at least one of the plurality of functional subpixels is disposed between two adjacent colored subpixels of the plurality of colored subpixels.

16. The display panel of claim 15, wherein the plurality of colored subpixels comprise red subpixels, green subpixels and blue subpixels.

17. The display panel of claim 15, wherein the plurality of functional subpixels comprise a light-transmitting subpixel, a fingerprint-sensing subpixel, a storage circuit subpixel or a combination thereof.

18. The display panel of claim 15, wherein the two adjacent colored subpixels are configured to display different colors.

19. The display panel of claim 15, wherein an area of each colored subpixel is substantially the same as an area of each functional subpixel.

20. The display panel of claim 15, wherein the display panel comprises an active matrix liquid crystal display (AMLCD) panel or an active matrix organic light-emitting diode (AMOLED) display panel.
